(19) United States
(12) Patent Application Publication
(10) Pub. No.: US 2002/0119259 A1
(43) Pub. Date: Aug. 29, 2002

(54) Method of applying a coating to a substrate

(76) Inventors: Sawako Kamei, Dublin, OH (US); Michael Wiseman, South Vienna, OH (US); Ashley Nichols, Hilliard, OH (US); Kenneth Keller, Plain City, OH (US)

Correspondence Address: BANNER & WITCOFF, 1001 G STREET N W, SUITE 1100, WASHINGTON, DC, 20001, US

(21) Appl. No.: 09/949,996

(22) Filed: Sep. 12, 2001

Related U.S. Application Data
(60) Provisional application No. 60/231,555, filed on Sep. 11, 2000.

(51) Int. Cl. C23C 14/00; B05D 1/36; B05D 3/02; B05D 3/06; B05D 5/06

(52) U.S. Cl. 427/558; 427/258; 427/407.1; 427/250; 427/385.5; 427/404

(57) ABSTRACT

A method is disclosed for coating a substrate in order to provide a component formed by the substrate with a desired aesthetic apperance. The method eliminates production steps, reduces production time and reduces production costs compared to known coating processes. This method comprises the steps of washing a substrate with a cleaning agent, rinsing said cleaning agent from the substrate and pouring or showering a waterborne adhesion promoter over the substrate. The method also includes the steps of heat flashing the substrate carrying the adhesion promoter, applying a base coat after the heat flash step has been completed and applying a decorative coating layer onto the substrate after the base coat has been applied. The method can also include the steps of applying a clear cover coat over the decorative coating layer and curing the clear cover coat to the substrate.

### CROSS-REFERENCES TO RELATED APPLICATIONS

This application claims benefit under 37 CFR 1.78 of provisional application number 60/231,555 filed on Sep. 11, 2000. The full disclosure of this provisional application is incorporated herein by reference.

### BACKGROUND OF THE INVENTION

The present invention relates to a method of coating a substrate in order to increase its esthetic appearance. More specifically, the present invention relates to a fast and inexpensive method of coating a substrate of a component that is intended to provide a desired aesthetic appearance, such as a metallic luster or a color that matches another component of a body.

It is well known to apply paints, metal film layers or other types of known coatings to component substrates in order to provide the component with a particular aesthetic appearance. These known coatings can be applied in various methods. Typically, the coating method depends on the type of substrate, the applied coating(s) and the desired aesthetic appearance of the component. For example, in the automotive industry, it is desirable to provide certain components, such as trim pieces, with a chrome-like appearance or a color that matches a body part. This is especially true for grilles and bumpers that have plastic substrates.

In order to provide the component with the desired aesthetic appearance, paints that match the color of the relevant body part or thin metal film layers are applied as one of a number of coatings on the substrate. The coatings include a base coat, an appearance creating coat and a top, cover coat. The cover coating is applied over the other coatings to protect them from being chipped or scratched. However, the desired aesthetic appearance may not always result. Factors that effect the final appearance include the materials used and the coating method employed. For example, the coating method may cause the brightness of a metallic film layer to be of a lesser magnitude than desired by the customer. Additionally, when the coated substrate is used to form an automobile bumper or grille, the manufacturer must consider that the layer providing the color or metallic appearance should not break or become visually damaged after experiencing a minor impact.

An additional problem that is faced by the manufacturer is how to ensure that the base coat and subsequent layers will adhere to the substrate. Typically, the substrates used for automobiles are plastic. Known plastic substrates include those formed of thermoplastic polyurethanes (TPU) or polyolefins. These polyolefins include thermoplastic olefins (TPO) containing polypropylenes. Because paints and other coating materials will not adhere directly to these plastic substrates, the substrates must be either formed with an additive that will enhance the adhesion between the substrate or a primer, sometimes referred to as solvent borne adhesion promoters, must be applied between the substrate and the base coat as disclosed in U.S. Pat. No. 5,711,993 to Lein et al. However, these primers are not true adhesion promoters because they are (1) thick, (2) create an undesirable, detectable film between the substrate and the base coat, (3) require the manufacturer to perform the extra step of painting, spraying or rolling them onto the substrate after the substrate has undergone initial pretreating steps in a pretreatment system and (4) require that the substrate be baked for an extended period of time, such as one to two hours, in order for the primer to cure.

The prior art coating processes that use these primers take an undesirably long time to complete. Additionally, their need to repeatedly bake (cure) the substrate significantly increases the operating costs of their associated coating lines. Moreover, as discussed above, the prior art coating processes can distort the color of the paint or metal film layer. As a result, the prior art methods for coating substrates used as automobile trim in order to provide them with desired esthetic appearances are very costly, limit the amount of production that can be achieved with any one coating line and may not provide the intended esthetic appearance.

Coating methods that require baking of a substrate for an extended period of time after the application of different coating layers are known in the art. One such example is U.S. Pat. No. 5,837,354 to Ogisu et al., which discloses a flexible metallized product and a method for producing the same. The disclosed product includes a substrate made of a soft resin material, a base coat formed on top of the substrate, a thin, metal film layer formed on the base coat and a top coat layer including a coating applied over the metal film layer. Ogisu does not disclose the use of an adhesion promoter. Instead, the substrate can include rubber-like components that introduce adhesive moieties onto the surface of the substrate to increase adhesion between the substrate and the base coat. After the base coat is applied, the substrate with its base coat is baked for one hour at an elevated temperature of 80° C. After the metal film layer has been formed, the coating which forms the top coat layer is applied. The substrate is again baked at 80° C. for one hour in order to form the top coat. Two of the steps disclosed in the Ogisu method take at least two hours to perform. This amount of time does not take into account the other steps which must also be performed. The elapsed time for performing the entire method could be upwards of three or more hours. Such a long period of time severely limits the number of products that can be formed in a single day.

Another example of an expensive, time consuming method is disclosed in U.S. Pat. No. 4,551,387 to Manabe et al. which describes a colored resinous article with concealed metallic luster and a method of forming the article. The article includes a resinous molded substrate that is covered by a polyurethane or UV-curable paint as a base layer. A metal film layer is positioned over the base coat and covered with a polyurethane or UV-curable paint as a top coat. A primer can also be provided between the substrate and the base coat for establishing a layer between these two components. Like the method disclosed in Ogisu, the method of Manabe et al. takes many hours to perform. For example, the method of forming the Manabe et al. product includes applying the base coat, allowing it to set for ten minutes, baking or curing it for two hours at 80° C., allowing it to set for ten minutes, applying the metal and top coat layers and then baking the product for an additional hour at 70° C. The method disclosed in Manabe et al. takes well over 3 and one-half hours to perform. More likely, the method takes over four hours and possibly upwards of five hours to perform completely. This total elapsed time makes the components very expensive to produce.

### SUMMARY OF THE INVENTION

The present invention relates to a method of applying a coating to a substrate which eliminates production steps, reduces production time and reduces production costs. The present invention includes a method of coating a flexible substrate so as to provide the component formed by the substrate with a desired aesthetic appearance. This method comprises the steps of washing a substrate with a cleaning agent, rinsing said cleaning agent from the substrate and applying a waterborne adhesion promoter to the substrate. The method also includes the steps of heat flashing the substrate carrying the adhesion promoter, applying a base coat after the heat flash step has been completed and applying a decorative coating layer onto the substrate after the base coat has been applied. The method can also include the steps of applying a clear cover coat over the decorative coating layer and curing the clear cover coat to the substrate.

The present invention also includes a method of coating a substrate including the step of preparing a substrate for receiving a plurality of coating layers. This preparation step includes applying a waterbome adhesion promoter to the substrate. The adhesion promoter assists in providing a strong bond between the substrate and a base coat after it cures on the substrate. The method further includes the steps of applying the base coat over the substrate and curing it using UV radiation. Additionally, the method comprises the steps of applying and curing a cover coat on said substrate to protect the substrate and the other coats from damage.

The present invention further includes a method of coating a substrate comprising the steps of preparing a substrate for receiving at least one coating layer, including applying an adhesion promoter to the substrate, curing the adhesion promoter on the substrate by applying heat for less than fifteen minutes and applying a first coat over the substrate after the adhesion promoter has cured.

The method of the present invention increases production while reducing costs and production time by eliminating time consuming steps that are associated with the prior art coating methods. The present invention does not require that the adhesion promoter be sprayed or otherwise applied to the substrate after the substrate has been initially treated. Instead, it applies a waterbome (water-based) adhesion promoter during the operation of an aqueous pretreatment system. Additionally, the present invention eliminates the need to bake the substrate and its coating more than once during the coating process. Moreover, the entire process can be performed in about one hour. By eliminating the prior art primer/adhesion promoter booth and the additional baking areas, the assembly line used to apply coatings according to the present invention is much more compact. As a result, more coating lines can be located in a single area when compared to the prior art coating lines.

### BRIEF DESCRIPTION OF THE DRAWINGS

FIG. 1 schematically illustrates a component formed by a method according to the present invention with an adhesion promoter having an enlarged thickness for clarity;

FIG. 2 schematically illustrates the method of preparing and coating a substrate according to the present invention;

FIG. 3 schematically shows an angle at which the substrate can be positioned as an adhesion promoter is dried;

FIG. 4 schematically illustrates an alternative embodiment of the method illustrated in FIG. 1; and

FIG. 5 schematically illustrates a pretreatment process according to the present invention.

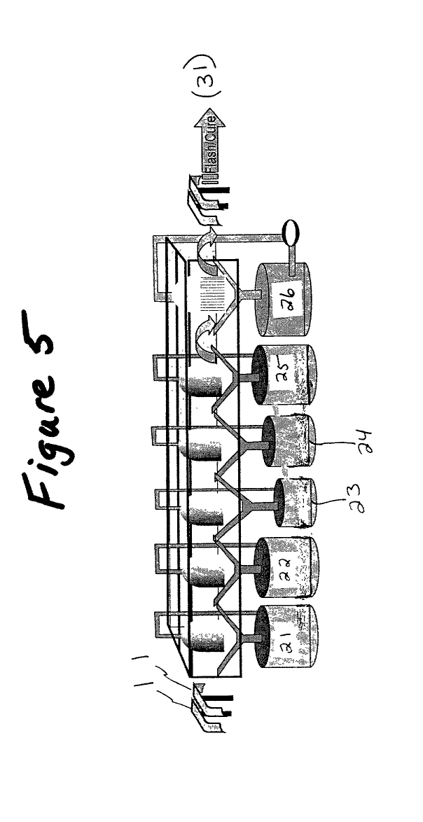

### DETAILED DESCRIPTION OF THE PREFERRED EMBODIMENT

The present invention relates to a method of coating a substrate in order to provide a surface with a desired aesthetic appearance. In this application, the term “component” is used to describe the substrate and all of the coating layers applied to it that create the desired aesthetic appearance. The components can be any part of a device that is given a colored or metallic appearance for decorative purposes. These devices include automobiles, other types of vehicles including trucks and SUV's, household appliances, plumbing fixtures, decorative hardware containers and/or their lids, frames, trophies, etc. Although not limited to its use in coating automobile component substrates, for simplicity, the invention will be described using automobile substrates that form part of an automobile grille or bumper.

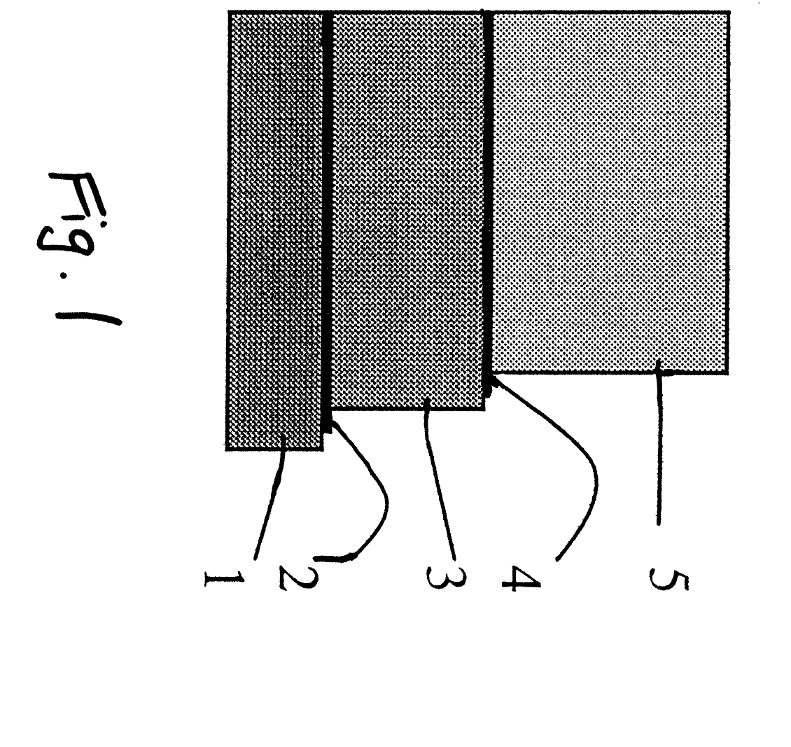

As shown in FIG. 1, the component includes a substrate 1 and plurality of coating layers that cover the substrate 1. As discussed below, these coating layers are sequentially applied to the substrate 1 in order to create the desired decorative appearance. Substrate 1 can have any shape. Typically, its shape depends on its ultimate use. For example, the substrate may have the shape of an automobile bumper if it is intended to form a portion of such a bumper. Substrate 1 and its shape can be formed using any known conventional process such as molding or extrusion.

Substrate 1 is formed of a plastic material that is capable of withstanding low impact collisions, is easily moldable into a variety of shapes and exhibits the physical properties of conventional automotive bumpers. Plastic materials that can be used in forming substrate 1 include polyolefins that are commercially available. One type of polyolefin that can be used is a thermoplastic olefin (TPO). In one embodiment, this TPO has a coefficient of linear thermal expansion (CLTE) of about 7.0 (7.0×10⁻⁵ (1/° C.)) or less. In a preferred embodiment, the TPO has a CLTE of about 3.0. This TPO is available from Color & Composite Technology (CCT) under the name HNB 171PK6. This material has a lower CLTE than conventional TPO's used for vehicle parts. However, any known TPO with a similar CLTE could be used. While not as preferred, polypropylenes could also be used for substrate 1. While also not as preferred, plastic materials such as those disclosed in U.S. Pat. Nos. 5,693,710 to Srinivasan et al. and 5,829,804 to Saeki et al. can also be used. Both of these U.S. patents are expressly incorporated herein by reference.

The substrate 1 is coated with a waterbome adhesion promoter 2. As discussed above, adhesion promoter 2 is different from a primer or solvent borne adhesion promoters. The waterborne adhesion promoters used with the present invention is typically about or less than 10 μm in thickness, it does not have the properties of a primer and its intended purpose is only to promote adhesion. More typically, the waterborne adhesion promoter has a thickness of about one micron. For example, adhesion promoters according to the present invention do not level the surface of the substrate 1 (as would a primer) and they are not intended to, and do not, create a film between the substrate 1 and a base coat 3. Adhesion promoters that can be used with the present invention include those that flow smoothly while maintaining their adhesion promoter physical properties. A preferred adhesion promoter is the preferred adhesion promoter described in U.S. Pat. No. 6,262,160, and co-pending U.S. patent application Ser. No. 09/500,657, filed Feb. 9, 2000, both of which are entitled “Water Base Adhesion Promotor for Polypropylene and Method for Coating to Polypropylene Materials Using the Promotor”, and both of which are hereby expressly incorporated by reference. This adhesion promoter causes a good bond to be formed between the TPO substrate 1, discussed above, and the base coat layer 3, discussed below. However, other adhesion promoters that have the above-discussed properties and will adhere to the TPO substrate 1 and the base coat layer 3 could also be used. These include the other adhesion promoters disclosed in U.S. patent application Ser. Nos. 09/248,235 and 09/500,657, and other known waterbome adhesion promoters such as chlorinated polyolefins and methylene chloride.

The base coat layer 3 is applied on top of the adhesion promoter 2. This base coat 3 adheres well to the adhesion promoter 2 and is flexible when bent so that delamination does not occur when flexed. The base coat 3 also levels the surface of the substrate 1 and presents a smooth surface for a decorative or appearance producing layer 4 to coat. As a result of its leveling function, the use of the base coat 3 eliminates the need for the primers used in the prior art. Additionally, the base coat 3 is radiation curable in order to reduce the duration of the curing process compared to the prior art. In one embodiment, the base coat is UV curable. In one embodiment, the base coat 3 comprises a backbone resin including one or more of the following: polyester, urethane and acrylate. The base coat 3 also includes cross linkers of polyester ether and/or acrylates. UV curable agents, such as photo initiators, are also provided in the resin of the base coat 3 to begin the polymer chain reaction in response to the application of radiation, such as the UV radiation. An example of a material that can be used for the base coat includes NRX-0001 available from Nippon Bee Research of America (NBRA).

Depending on the layer 4 which is applied on top of the base coat 3, the base coat 3 can either be clear or include pigments or other known coloring agents. The base coat 3 will typically be clear if a metal film is applied as a decorative or appearance producing coating layer 4. In one embodiment, the color of the base coat does not alter the effect of the metal film layer. In an alternative embodiment, the color of the base coat can alter the effect of the metal film layer. Similarly, if certain effects are intended, then a colored paint could be used below the metal film layer as the base coat 3. If decorative layer 4 includes another layer of a paint, then base coat 3 can either be clear or include some pigment or known coloring agent which complements and enhances the aesthetic appearance of the decorative layer 4.

As discussed above, the decorative (appearance producing coating) layer 4 can be comprised of either a thin, metal film or a pigmented or otherwise colored paint that coordinates with another body portion of the automobile. If a thin metal layer is used, it is applied using well known metallizing techniques that cover at least a portion of the base coat 3 with a metal. These metallizing techniques can include chemical vapor deposition (CVD), physical vapor deposition (PVD), vacuum metallizing, sputtering or that disclosed in U.S. patent. application Ser. No. 5,837,354 to Ogisu et al, which is hereby expressly incorporated by reference. In one embodiment, PVD is used to cover base coat 3 with a thin, bright metal film or sheet that forms a chrome-like effect on the exterior surface of the finalized component. In this embodiment, a magnetron sputtering machine from Leybold Industries of Germany is used. The rapid metallization provided by this Leybold sputtering machine adds very little heat load to the substrate over the heat distortion temperature (HDT) of the material.

The shape of the substrate and the desired aesthetic appearance are factors that determine the color and selection of the metal. The thin metal films can be of any known thickness. Such thicknesses are disclosed in the U.S. Patents that are incorporated by reference. The bright metal films of layer 4 can include, for example, aluminum, chromium, indium, nickel chromium, such as nickel 80%, chromium 20%, stainless steel or combinations of these metals that are flexible and able to resist breakage under low level impacts. Other similar materials can also be used.

Alternatively, as discussed above, layer 4 could be formed of a colored paint that provides the substrate with desired aesthetic appearance. The paint can be any well known, polyurethane or UV curable paint that exhibits good adhesion to the chosen base coat 3. Metal flakes could be added to the paint if a metallic, painted finish was desired.

Layer 5 includes a clear or top coat that is applied over layer 4 to protect it from being scratched, pitted or otherwise damaged. Top coat layer 5 can be any one of the flexible, polyurethane paints or protective UV curable paints or coating materials that are well known in the art and require a very short curing time. In one embodiment, the top coat 5 can include a 2 K urethane material conventionally used in the automotive industry. This material has a bake temperature in the range of about 80 to 100 degrees Celsius and should protect against the scratching, marring and corrosion of the decorative layer 4. Well-known UV curable materials that could be used in top coat 5 include those disclosed in U.S. Pat. Nos. 4,551,387 and 5,985,418. R-788 available from Morton, Nippon Coating Co., Ltd. can also be used on parts of an automobile such as the bumper. A top coat paint that can be used with the present invention is a polyester resin paint sold by Morton Nippon Coatings Co., Ltd. under the number NRX-9202. While not preferred because of the large amounts of time needed to cure them, the top coat layers disclosed in U.S. Pat. No. 5,837,354 to Ogisu et al. may also be used.

The method of coating the substrate 1 according to the present invention includes two procedures. Each of these procedures has multiple stages. The first procedure is the pretreatment procedure 20 that utilizes a pretreatment system for removing dirt, grease, etc. from the substrate so that it is ready to receive the base coat 2. The second procedure is the coating procedure 30 that includes the steps of applying layers 2-5 on top of the substrate 1.

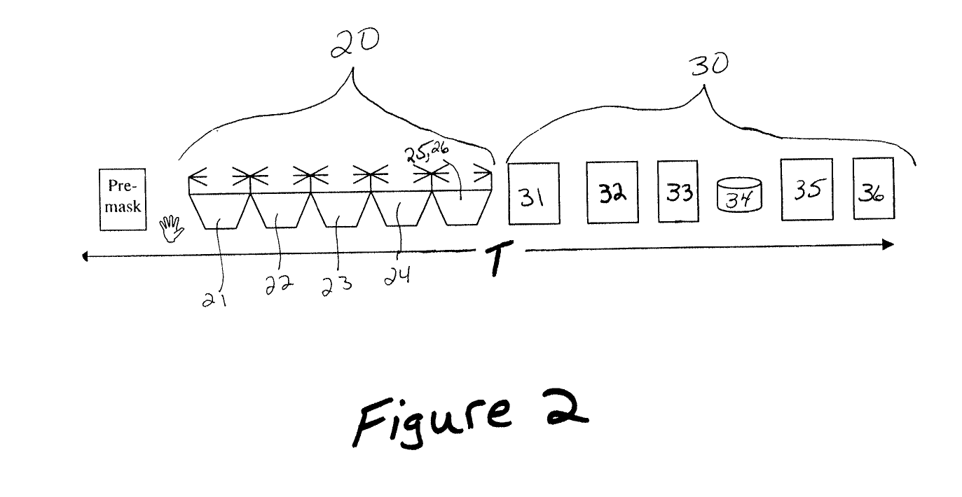

In the first, pretreatment procedure, the substrate 1 undergoes various cleaning and preparing steps in an aqueous degrease power wash line. During the pretreatment procedure, the substrate 1 can remain in a single location and the equipment for accomplishing the cleaning and preparing steps moves with respect to the substrate 1. Alternatively, the substrate 1 can be moved along an assembly line past stages where each of the pretreatment steps are performed. As shown in FIG. 2, the first stage 21 includes rinsing the substrate with a rinsing agent such as warm water at about 60° C. to 80° C. However, other well known rinsing agents can be used in place of the water. The rinsing agent can be sprayed directly onto the substrate 1. The temperature of the applied rinsing agent depends on the particular agent being used.

After the substrate 1 has been initially rinsed, it undergoes a degreasing stage 22. During this degreasing stage, the substrate 1 is washed with a cleaning agent, such as an alkaline cleaning agent. The cleaning agent is applied by spraying or pouring. Preferred cleaning agents that can be used with the present invention include Surf Cleaner PL-1000, produced by Nippon Paint Co., Ltd.

After it has been washed and degreased, the substrate 1 is repeatedly rinsed at stages 23, 24 and 25 to remove the alkaline cleaning agent from its surface. Room temperature deionized water is sprayed onto the substrate 1 at both of these stages in order to remove the cleaning agent. However, the deionized water could be applied to the substrate 1 in any known manner that results in the complete removal of the cleaning agent. Unlike the prior art pretreatment procedures, the present invention does not require the use of a surface conditioner in the final rinsing stage. Instead, the present invention uses the adhesion promoter to perform this function.

The final stage 26 in the pretreatment procedure 20 includes the application of the adhesion promoter 2 onto the substrate 1. As discussed above, the adhesion promoter must be able to flow smoothly without losing its adhesion properties. Also, for safety considerations, it is preferable that the adhesion promoter be waterbome. In the present invention, the adhesion promoter is applied to the substrate by pouring, dipping or showering. The adhesion promoter flows over the substrate. The amount that remains on the substrate after this stage 25 has concluded is sufficient to promote adhesion. Any poured or showered promoter that does not stay on the substrate 1 can be recollected and recirculated (recycled) because of the nature of its application and its ability to flow. This provides the method with a high degree of efficiency. While the adhesion promoter could be sprayed, this is not preferred because aspiration increases the surface area exposed to air and the solvents deplete faster.

When the substrate arrives at stage 26, it is carrying a constant amount of distilled water from the previous stage 25. This water dilutes the adhesion promoter over time. In theory, the surface area of the substrate 1 and environmental conditions will dictate the amount of water carried into the adhesion promoter, as well as the amount of carry out. Adjustments are made as necessary, according to the amount of solids (% NV), pH, conductivity, surface tension, and visual appearance of the material. These adjustments are made by adding solvents (water or solvents), concentrates and/or additives. The adjustments can be made continuously with expensive control equipment, or by a schedule similar to other pretreatment chemicals.

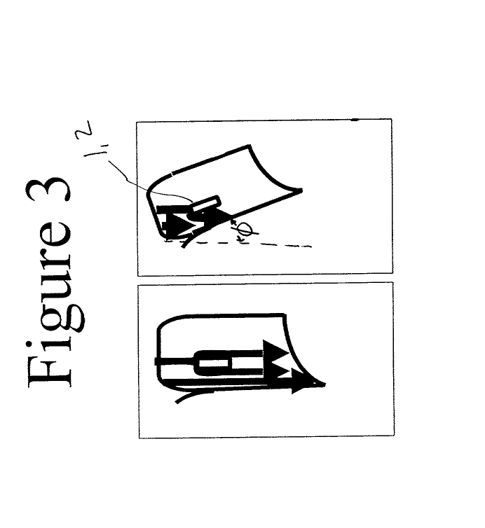

The substrates 1 and adhesion promoter 2 can be dried while horizontally positioned. However, this could allow the adhesion promoter 2 to pool on the surface of the substrate 1. Alternatively, they could be dried while in a vertical position (standing up straight). In a preferred embodiment, the substrates 1 are hung or otherwise vertically supported at an angle to minimize the distance the adhesion promoter has to travel off the substrate 1, as shown in FIG. 3. The angle Ø can be between about 5 and 35 degrees with a preferred angle for the substrates 1 being substantially 15 degrees from vertical (see FIG. 3). Hanging the substrates at an angle results in the elimination of drip lines and sag marks that cannot be hidden by the base coat 3 and the clear coat 5. The substrates can be hung from between about 30 seconds and 10 minutes depending on the condition of the room and the adhesion promoter used. In a preferred embodiment using the preferred adhesion promoter described in the above incorporated copending U.S. Patent Applications, the substrates are hung for about one minute at room temperature before moving on to stage 31. Room temperature can be between about 15° C. and 30° C. with about 40 to 70 percent relative humidity. One preferred room condition is between about 20° C. and 25° C. with about 40 to 70 percent humidity.

After the step of applying the adhesion promoter 2 has been completed at stage 26, the substrate 1 carrying the adhesion promoter 2 is subjected to a heat flash stage 31. This heat flash stage 31 forms the initial step of the coating procedure 30. At this stage, the substrate 2 and adhesion promoter 3 are positioned in a drying oven 55 and dried (subjected to a heat flash) at a temperature between about 60° C. and 120° C. for between about 5 and 20 minutes. The heat flash can be conducted using ovens such as hot-air drying ovens, long-wave infrared ovens and short-wave infrared ovens. In a preferred embodiment, the substrate and adhesion promoter are dried for about 10 minutes at about 80° C. This is a relatively low temperature and time compared to the prior art. However, any amount of time or temperature that is necessary to drive off the water in the waterbome adhesion promoter is contemplated. Any film that results from the curing of the adhesion promoter is invisible, undetectable and acts like an activator on the surface of substrate (TPO). Such a film would have a thickness of between about 0.1 and 1 μm.

After the water is driven off, the base coat 3 is applied to substrate 1. The base coat 3 is applied using traditional techniques such as spray coating at stage 32. The base coat 3 and the substrate 1 are then cured by the application of UV radiation at stage 33. After the UV radiation cures the base coat 3 on the substrate 1, the thin metal film layer 4 is applied by well known methods such as those discussed above including CVD and PVD in order to provide a metallic aesthetic appearance. Alternatively, as discussed above, paint with or without metal flakes can be applied over the cured base coat in place of the metal film layer. When performed, these steps occur at stage 34.

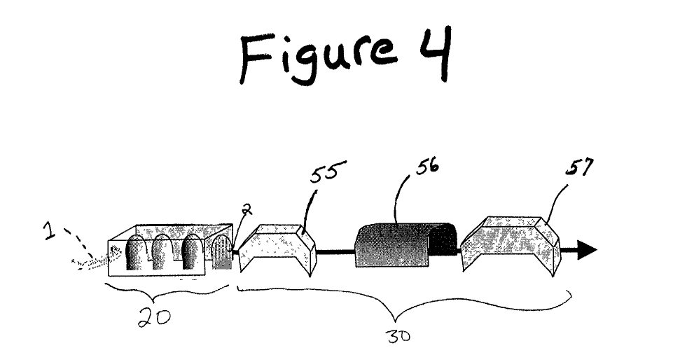

After the metal film layer 4 has been applied to the substrate 1, the top or cover coat 5 is applied by spraying or other known methods at stage 35. This spraying is typically conducted in a spray booth 56. The cover coating is then subjected to UV radiation at stage 36 and cured as disclosed in the above discussed references that are incorporated by reference. In addition to or in place of the UV curing, the entire component can be cured in an oven as shown in FIG. 4 after the clear cover coating has been applied. This overall curing is accomplished by baking the component at between about 60° C. and 100° C. for about 20 to 40 minutes in another oven 57. It is contemplated that oven 55 could also be used. In a preferred embodiment, the component is baked at about 80° C. for about 30 minutes in oven 57. The total process time T of the method according to the present invention (illustrated in FIG. 2) is between approximately one hour and one hour and thirty minutes.

According to the present invention, an adhesion promoters is a coating applied to a substrate before it is top coated to improve intercoat adhesion. Primers can perform the function of improving the adhesion between layers, but they are thicker than adhesion promoters and do not evaporate after being subjected to heat. Instead, as discussed above, a primer forms a noticeable, normally intended, continuous layer on the substrate or base material. The adhesion promoter according to the present invention is further distinguished from a primer surfacer that is a composition for filling minor irregularities to obtain a smooth, uniform surface preparatory to applying a finishing coat.

While the invention has been described in the manner presently conceived to be most practical and a preferred embodiment thereof, it will be apparent to persons ordinarily skilled in the art that modifications may be made thereof within the scope of the invention, which scope is to be accorded the broadest interpretation of the claims such as to encompass all equivalents, devices, and methods.

We claim:

1. A method of coating a substrate to provide a predetermined aesthetic effect, said method comprising the steps of:
a) preparing a substrate for receiving a base coat, said preparing step including the step of applying an adhesion promoter to said substrate;
b) heat flashing said adhesion promoter on said substrate;
c) applying a base coat over said substrate after said heat flashing step has been completed;
d) curing said base coat so that said base coat forms a layer on said substrate;
e) applying a decorative coat to said substrate; and
f) applying a cover coat over the decorative coat to protect said decorative coat from being damaged.

2. The method of claim 1 further including the step of curing said decorative coat on said substrate.

3. The method of claim 1 wherein said decorative coat includes a metal film layer; and said step of applying a decorative coat includes metallizing said metal film layer on said base coat.

4. The method of claim 1 wherein said heat flashing step includes exposing said substrate and adhesion promoter to a heat source for less than fifteen minutes.

5. The method of claim 1 wherein said preparing step further includes the steps of:
a) cleaning said substrate to remove dirt and grease; and
b) rinsing said substrate.

6. The method of claim 1 wherein said step of applying the adhesion promoter includes the step of showering or pouring the adhesion promoter over said substrate.

7. The method of claim 6 wherein the step of applying the adhesion promoter further includes the step of recycling adhesion promoter that moves off the substrate.

8. The method of claim 1 further including the step of curing said cover coat.

9. The method of claim 8 wherein said step of curing the cover coat includes applying UV radiation to said cover coat and said substrate.

10. The method of claim 8 wherein said step of curing said cover coat includes baking said substrate after said cover coat has been applied.

11. The method of claim 10 wherein said substrate and cover coat are baked for less than 45 minutes.

12. The method of claim 1 wherein said step of curing said base coat includes applying UV radiation to said base coat and substrate.

13. The method of claim 1 wherein said cover coat is clear.

14. The method of claim 1 further including the step of forming the substrate of a flexible material so that said substrate is flexible.

15. The method of claim 1 wherein each of said substrate, base coat, decorative coat and cover coat are flexible.

16. A method of coating a substrate, said method comprising the steps of:
a) preparing a substrate for receiving a plurality of coating layers, said preparing step including the step of applying a waterborne adhesion promoter to said substrate;
b) curing said waterborne adhesion promoter on said substrate;
c) applying a base coat over said substrate after said adhesion promoter has cured;
d) applying UV radiation to said base coat to cure said base coat on said substrate;
e) applying a cover coat; and
f) curing said cover coat on said substrate.

17. The method according to claim 16 wherein said base coat includes a decorative paint.

18. The method according to claim 16 further including the step of applying a decorative coat to said substrate before said cover coat is applied.

19. The method according to claim 18 wherein said decorative coat includes a metal film layer; and said step of applying a decorative coat includes a step of metallizing said metal film layer on said base coat.

20. The method according to claim 19 wherein said metallizing step includes applying said metal film by sputtering.

21. The method according to claim 19 wherein said metallizing step includes applying said metal film by physical vapor deposition.

22. The method according to claim 16 wherein said step of curing said waterborne adhesion promoter include heat flashing said adhesion promoter to drive off excess water.

23. The method according to claim 22 wherein said heat flashing includes exposing said substrate and adhesion promoter to a heat source for less than fifteen minutes.

24. The method according to claim 16 wherein said preparing step further includes the steps of:
a) cleaning said substrate to remove dirt and grease; and
b) repeatedly rinsing said substrate.

25. The method according to claim 16 wherein said step of applying the adhesion promoter includes the step of showering or pouring the adhesion promoter over said substrate.

26. The method according to claim 25 wherein the step of applying the adhesion promoter includes the step of recycling any adhesion promoter that moves off the substrate.

27. The method according to claim 16 wherein said step of curing the cover coat includes applying UV radiation to said cover coat and said substrate.

28. The method according to claim 16 wherein said step of curing said cover coat includes baking said substrate after said cover coat has been applied.

29. The method according to claim 28 wherein said substrate and cover coat are baked for less than 45 minutes.

30. The method according to claim 16 further including the step of forming the substrate of a flexible material so that said substrate is flexible.

31. The method according to claim 16 wherein each of said substrate, base coat and cover coat are flexible.

32. A method of coating a substrate, said method comprising the steps of:
a) preparing a substrate for receiving at least one coating layer including the step of applying an adhesion promoter to said substrate;
b) curing said adhesion promoter on said substrate by applying heat for less than fifteen minutes; and
c) applying a first coat over said substrate after said adhesion promoter has cured.

33. The method of claim 32 wherein said first coat is a base coat; and further including the step of curing said first coat over said substrate.

34. The method of claim 33 further including the steps of:
a) applying a metal film over the cured first coat to provide the substrate with a metallic aesthetic appearance; and
b) applying a cover coat over said metal film for protecting said metal film layer from being damaged.

35. The method of claim 34 wherein each of said substrate, base coat, metal film and cover coat are flexible.

36. The method of claim 32 further including the step of forming the substrate of a flexible material so that said substrate is flexible.

37. The method of claim 32 wherein each of said substrate and said first coat are flexible.
